(19) United States
(12) Patent Application Publication
(10) Pub. No.: US 2025/0316484 A1
(43) Pub. Date: Oct. 9, 2025

(54) SEMICONDUCTOR DEVICE AND METHOD FOR FABRICATING SAME

(71) Applicant: Hangzhou HFC Semiconductor Co., Hangzhou (CN)

(72) Inventors: Lixiang GAO, Hangzhou (CN); Mao SUN, Hangzhou (CN); John H Zhang, Altamont, NY (US)

(21) Appl. No.: 18/639,031

(22) Filed: Apr. 18, 2024

(30) Foreign Application Priority Data
Apr. 4, 2024 (CN) 202410244502.2

(51) Int. Cl. H01L 21/28; H01L 21/8234

(52) U.S. Cl. CPC H01L 21/28123; H10D 84/0151; H10D 84/038

(57) ABSTRACT

A semiconductor device and method for fabricating the device are disclosed. The method includes: providing a substrate, on which multiple gate structures are formed, a first mask layer formed on tops of the gate structures, and spacers formed on side walls thereof, and a first interlayer dielectric layer formed between adjacent gate structures; partially removing the first interlayer dielectric layer; forming a second interlayer dielectric layer covering the first mask layer; forming a second mask layer and etching it so that at least one opening is formed, which exposes the second interlayer dielectric layer and is aligned with at least a portion of the gate structure and the spacers; partially removing the second interlayer dielectric layer; removing the exposed first mask layer and portions of spacers on both sides thereof; removing the exposed gate structures; and removing the second mask layer and filling it with a third interlayer dielectric layer.

### CROSS-REFERENCE TO RELATED APPLICATION

This application claims the priority of Chinese patent application number 202410244502.2, filed on Mar. 4, 2024, and entitled “SEMICONDUCTOR DEVICE AND METHOD FOR FABRICATING SAME”, the entire contents of which are incorporated herein by reference.

### TECHNICAL FIELD

The present invention relates to the field of semiconductor technology and, in particular, to a semiconductor device and method for fabricating the device.

### BACKGROUND

As semiconductor technology is continually advancing, semiconductor process nodes have shown a scaling-down trend in agreement with the Moore's law. In concert with this shrinking trend of process nodes and a trend of semiconductor devices towards high degrees of integration, the critical dimension (CD) of metal oxide semiconductor (MOS) devices, including gate length and pitch, is also decreasing. In the current gate structure fabrication processes, gates are usually formed by cutting elongate structures, and after cutting, the gates come into correspondence with respective transistors. This is helpful in increasing integration of the transistors.

FIGS. 1 to 5 are schematic diagrams showing intermediate structures resulting from process steps in a conventional method for fabricating a semiconductor device. Referring to FIG. 1, a plurality of gate structures 11 are formed on a substrate 10. A first mask layer 12 is formed on the gate structures 11, and spacers 13 are formed on side walls of the gate structures 11 and the first mask layer 12. A first interlayer dielectric 14 is formed between the gate structures 11 on the substrate 10. Referring to FIG. 2, a second mask layer 16 is formed and etched so that at least one opening 17 is formed therein, wherein the opening 17 exposes a portion of the gate structure 11 and a portion of the first interlayer dielectric layer 14 surrounding these gate structures 11. Referring to FIG. 3, with the second mask layer 16 serving as a mask, the exposed first mask layer 12, spacer(s) 13 and gate structures 11 are removed, so as to form trenches exposing the substrate 10. In this way, cutting of the gate structures is achieved. Referring to FIG. 4, other first interlayer dielectric 14 is formed and a chemical mechanical polishing (CMP) process is performed thereon so that the other first interlayer dielectric 14 only fills the trenches. Referring to FIG. 5, the first interlayer dielectric 14 is partially removed, and a second interlayer dielectric layer 18 is formed, preferably using a high-density plasma chemical vapor deposition (HDP-CVD) process.

In this method, during the etching process performed after the second mask layer 16 is formed for forming the openings 17 therein, partial loss of the first mask layer 12 underlying the openings 17 is inevitable. As a consequence, the gate structures 11 and the first mask layer 12, and hence the subsequently-formed gates, may be overall reduced in height. Further, during the CMP process performed after the other first interlayer dielectric 14 is formed, since the first interlayer dielectric layer 14 is a field oxide layer made of a material softer than a material of the second interlayer dielectric layer 18, difficulties are added to the CMP process.

### SUMMARY OF THE INVENTION

It is an object of the present invention to provide a semiconductor device and a method for fabricating the device, which can mitigate gate height loss.

In a first aspect of the present invention, a method for fabricating a semiconductor device is provided, wherein the method comprises:
providing a substrate, on which a plurality of gate structures are formed, wherein a first mask layer is formed on tops of the gate structures; spacers are formed on side walls of the gate structures and the first mask layer; a first interlayer dielectric layer is formed on the substrate between adjacent gate structures; and a top of the first interlayer dielectric layer is flush with the top of the first mask layer;
removing a portion of the first interlayer dielectric layer so that the top of the first interlayer dielectric layer is lower than the top of the first mask layer;
forming a second interlayer dielectric layer, which fills up gaps between adjacent portions of the first mask layer and covers the first mask layer;
forming a second mask layer on the second interlayer dielectric layer and forming at least one opening that exposes the second interlayer dielectric layer by etching the second mask layer, wherein the opening is aligned with at least a portion of the gate structure and the spacers on both sides thereof;
with the second mask layer serving as a mask, forming a first trench by removing a portion of the second interlayer dielectric layer until the first mask layer is exposed;
forming a second trench by removing the first mask layer exposed in the first trench and reducing the height of spacers on both sides thereof;
forming a third trench by removing the gate structure exposed in the second trench; and
removing the second mask layer, forming a third interlayer dielectric layer which fills up the third trench, and planarizing the third interlayer dielectric layer until the first mask layer is exposed.

In a second aspect of the present invention, a semiconductor device made according to the method as defined above is provided, the semiconductor device comprises:
a substrate;
a plurality of gate structures located on the substrate, wherein a first mask layer is formed on tops of the gate structures, and wherein spacers are formed on side walls of the gate structures and the first mask layer;
a first interlayer dielectric layer located on the substrate between adjacent gate structures;
a second interlayer dielectric layer located on the substrate between adjacent gate structures and located on the first interlayer dielectric layer;
a third trench extending through a portion of the gate structure and exposing a portion of the substrate so as to provide a discontinuation for the gate structure,
wherein lower portions of side walls of the third trench are covered by the spacers; and
a third interlayer dielectric layer filled in the third trench.

In summary, in the semiconductor device and method of the present invention, the first interlayer dielectric layer is first partially removed so that its top is lower than that of the first mask layer. The second interlayer dielectric layer is then formed, which fills up the gaps between adjacent portions of the first mask layer and covers the first mask layer. Subsequently, the second mask layer is formed on the second interlayer dielectric layer and etched so that the opening is formed. As the second mask layer is located on the second interlayer dielectric layer, the first mask layer underlying the second interlayer dielectric layer will not be damaged during the etching of the second mask layer. Thus, subsequent gate height loss can be prevented.

In addition, the remaining portions of the spacers that survive from removing the exposed first mask layer and reducing the height of the spacers on both sides thereof can prevent collapsing of the first interlayer dielectric layer, as well as damage to the sources/drains during the removal of the exposed gate structures.

### BRIEF DESCRIPTION OF THE DRAWINGS

FIGS. 1 to 5 are schematic diagrams showing intermediate structures resulting from process steps in a conventional method for fabricating a semiconductor device.

FIG. 6 is a flowchart of a method for fabricating a semiconductor device according to an embodiment of the present invention.

FIGS. 7 to 21 are schematic diagrams showing intermediate structures resulting from process steps in a method for fabricating a semiconductor device according to an embodiment of the present invention.

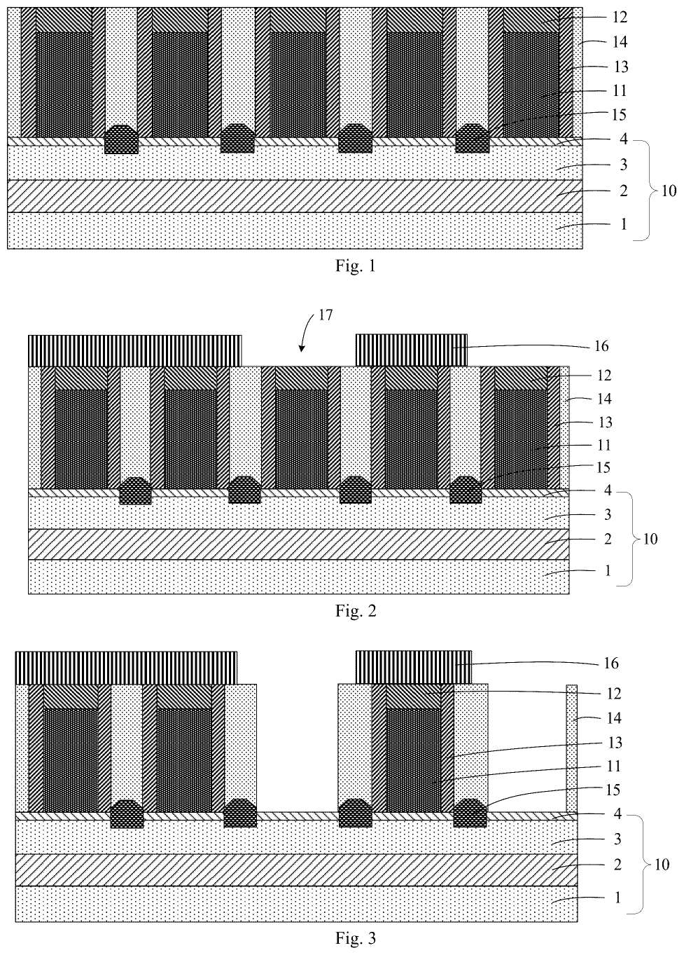

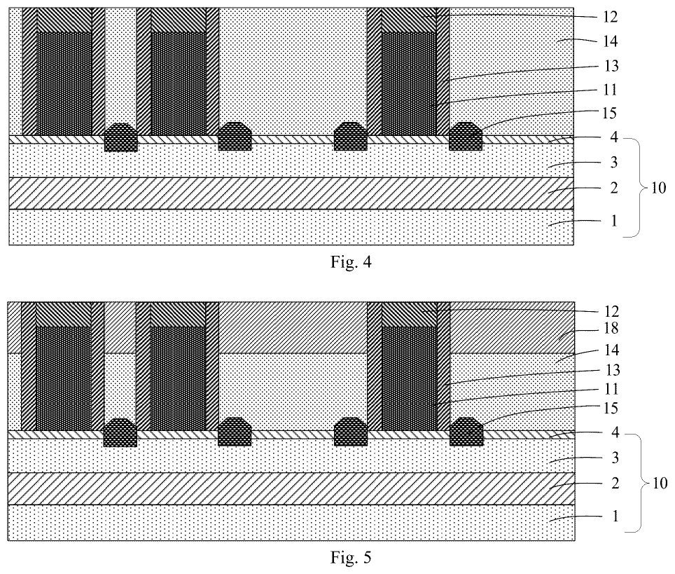

In these figures,
10, a substrate; 1, a bottom semiconductor layer; 2, a buried oxide layer; 3, a top semiconductor layer; 4, a capping oxide layer; 11, a gate structure; 12, a first mask layer; 13, a spacer; 14, a first interlayer dielectric layer; 15, a source/drain; 16, a second mask layer; 17, an opening; 18, a second interlayer dielectric layer; 191, a first trench; 192, a second trench; 193, a third trench; and 20, a third interlayer dielectric layer.

### DETAILED DESCRIPTION

Objects, advantages and features of the present invention will become more apparent upon reading the following more detailed description of specific embodiments thereof with reference to the accompanying drawings. Note that the figures are provided in a very simplified form not necessarily drawn to exact scale and for the only purpose of facilitating easy and clear description of the embodiments.

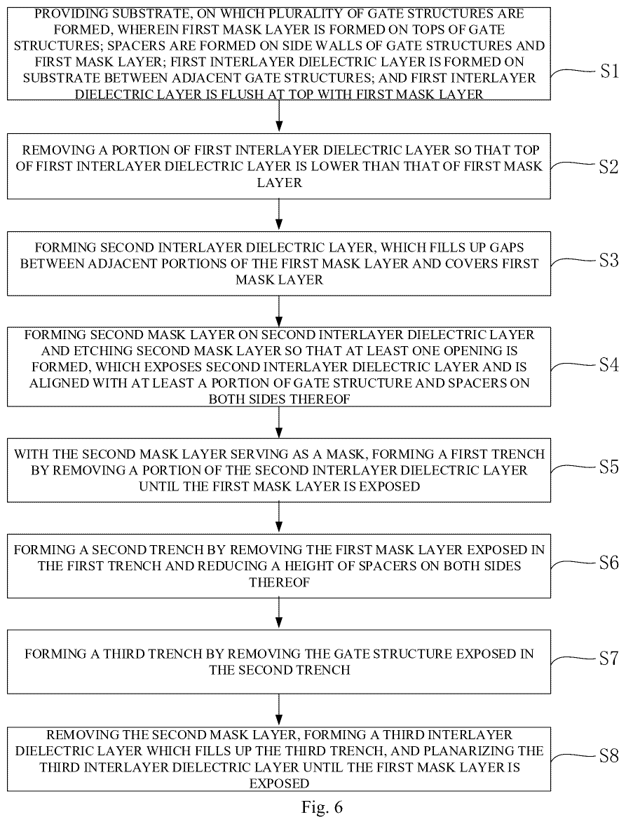

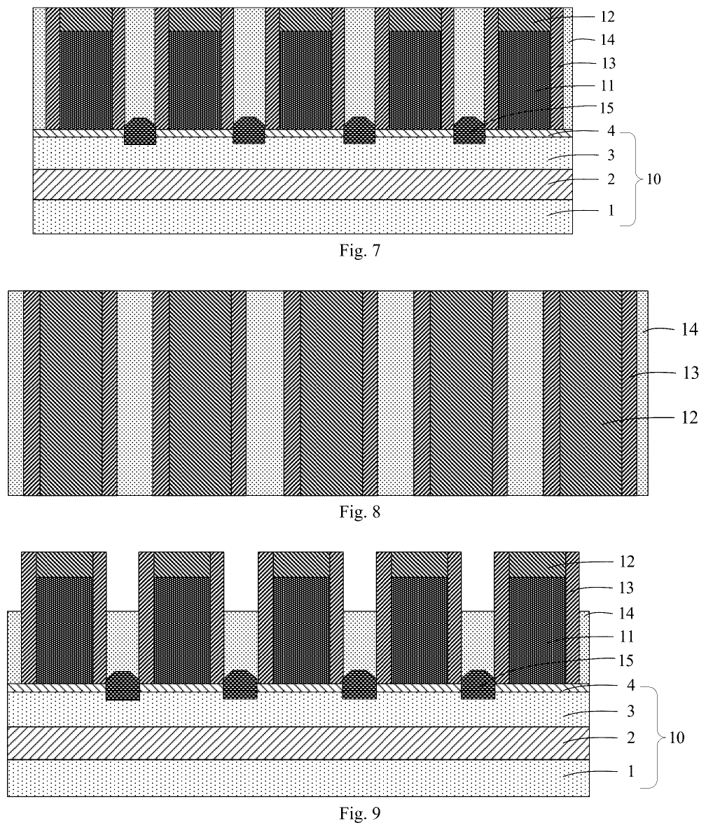

FIG. 6 is a flowchart of a method for fabricating a semiconductor device according to an embodiment of the present invention. FIGS. 7 to 21 are schematic diagrams showing intermediate structures resulting from process steps in a method for fabricating a semiconductor device according to an embodiment of the present invention. In FIGS. 7 to 21, FIGS. 7,9,10,12,14,16,18 and 20 are cross-sectional views, and all the remaining figures are top views. In the following, methods for fabricating a semiconductor device according to embodiments of the present invention will be described in detail with reference to FIGS. 6 and 7 to 21.

In step S1, referring to FIGS. 7 and 8, a substrate 10 is provided, on which a plurality of gate structures 11 are formed. A first mask layer 12 is formed on tops of the gate structures 11, and spacers 13 are formed on side walls of the gate structures 11 and the first mask layer 12. A first interlayer dielectric layer 14 is formed between adjacent gate structures 11 on the substrate 10. The top of the first interlayer dielectric layer 14 is flush with the top of the first mask layer 12.

According to an embodiment of the present invention, the substrate 10 is a semiconductor-on-insulator (SOI) substrate including a stack of a bottom semiconductor layer 1, a buried oxide layer 2 and a top semiconductor layer 3. Additionally, there may be a capping oxide layer 4 formed on the top semiconductor layer 3 and sources/drains 15 formed in the substrate 10 between the gate structures 11.

According to an embodiment of the present invention, the first interlayer dielectric layer 14 is a field oxide layer which is, for example, silicon oxide.

According to an embodiment of the present invention, the first mask layer 12 and the spacers 13 are made of the same material which is for example, silicon nitride.

In step S2, referring to FIG. 9, portions of the first interlayer dielectric layer 14 is removed so that the top of the remaining portions of the first interlayer dielectric layer 14 is lower than the top of the first mask layer 12.

According to an embodiment of the present invention, the portions of the first interlayer dielectric layer 14 may be removed by using a SiCoNi process, which is an etch-back process performed on the first interlayer dielectric layer 14. The top of the remaining portions of the first interlayer dielectric layer 14 may also be lower than the top of the gate structures 11.

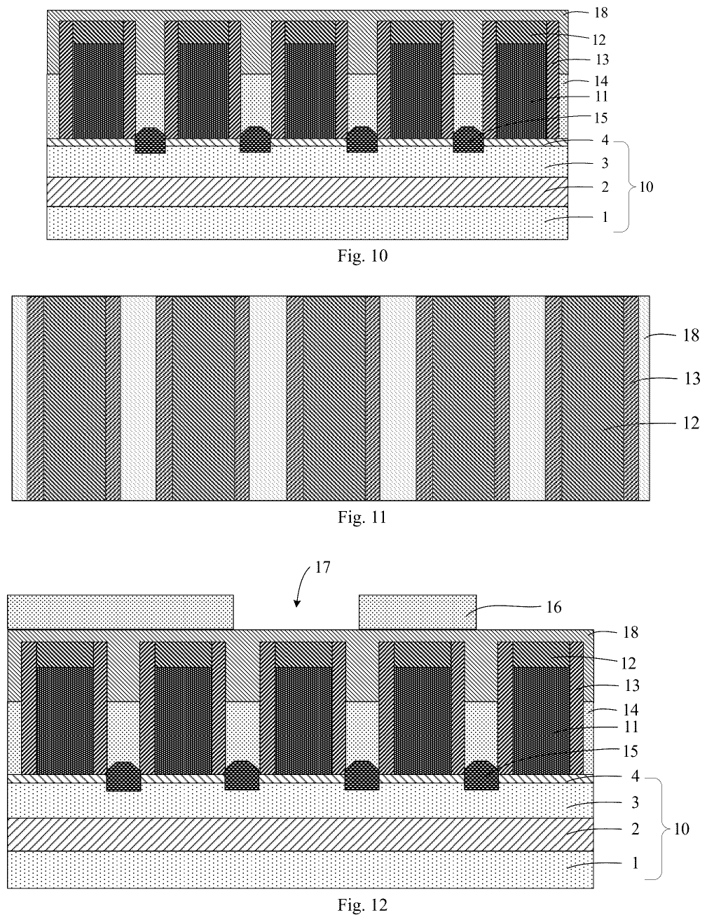

In step S3, referring to FIGS. 10 and 11, a second interlayer dielectric layer 18 is formed, which fills up gaps between adjacent portions of the first mask layers 12 and covers the first mask layer 12.

For example, an initial second interlayer dielectric layer (not shown) is first formed, which covers both the first interlayer dielectric layer 14 and the first mask layer 12. That is, the initial second interlayer dielectric layer fills up the gaps between adjacent gate structures 11 and covers the first mask layer 12. The initial second interlayer dielectric layer is then planarized so that the second interlayer dielectric layer 18 is formed and that a height difference between the tops of the second interlayer dielectric layer 18 and the first mask layer 12 lies within a predetermined range. The planarization may be accomplished with a chemical mechanical polishing (CMP) process, for example.

The top of the second interlayer dielectric layer 18 is higher than the top of the first mask layer 12. According to a non-limiting embodiment of the present invention, the height difference between the tops of the second interlayer dielectric layer 18 and the first mask layer 12 lies between 200 Å and 600 Å (i.e., the predetermined range).

The second interlayer dielectric layer 18 may be formed of, for example, silicon oxide, using a high-density plasma chemical vapor deposition (HDP-CVD) process.

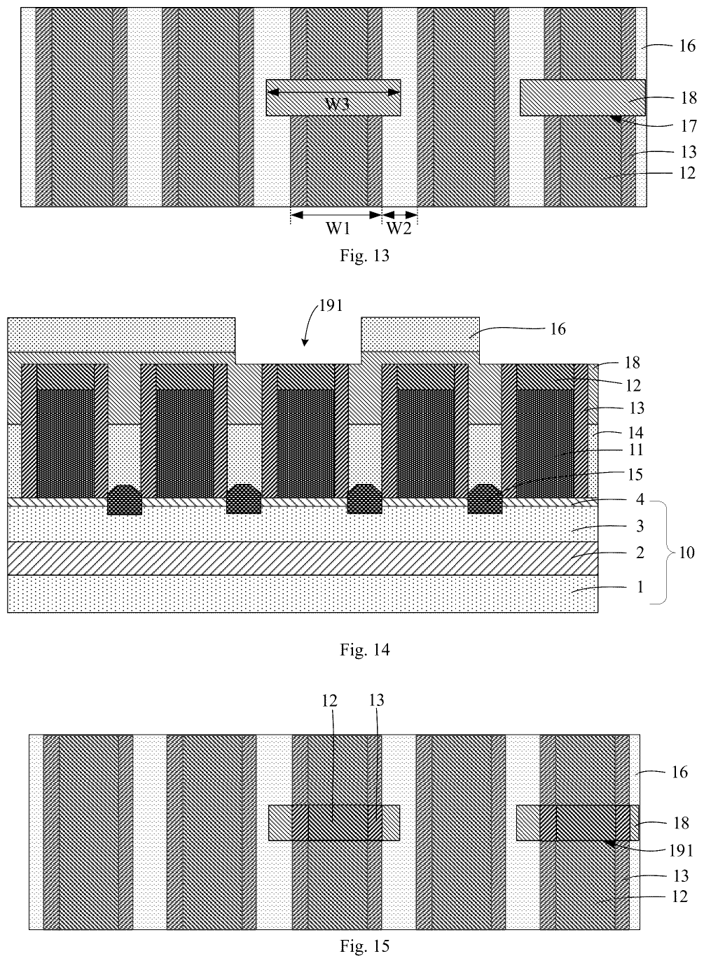

In step S4, referring to FIGS. 12 and 13, a second mask layer 16 is formed on the second interlayer dielectric layer 18 and etched so that at least one opening 17 is formed, which exposes the second interlayer dielectric layer 18. The opening 17 is aligned with at least a portion of the gate structure 11 and the spacers 13 on both sides thereof.

Referring to FIG. 13, a total cross-sectional width of each gate structure 11 and the spacers 13 on its both sides are denoted as W1, a cross-sectional width between adjacent spacers 13 of adjacent gate structures 11 is denoted as W2 and a cross-sectional width of the opening 17 is denoted as W3, where W1≤W3≤W1+2*W2.

According to an embodiment of the present invention, the second mask layer 16 is a photoresist layer, which is subjected to exposure and development, so as to form the opening 17 exposing the second interlayer dielectric layer 18.

In this embodiment, during the etching process for forming the opening 17 in the second mask layer 16, as the second interlayer dielectric layer 18 is to be exposed in the opening 17, the first mask layer 12 underlying the second interlayer dielectric layer 18 will not be damaged, thus avoiding any subsequent gate height loss.

Moreover, in this embodiment, the second mask layer 16 is formed on the second interlayer dielectric layer 18 after the first interlayer dielectric layer 14 is etched back and the second interlayer dielectric layer 18 is filled in the resulting gaps. Compared with the prior art, it is no longer necessary to form other first interlayer dielectric layer 14 and carry out a CMP process thereon. Therefore, no difficulties will be added to the CMP process.

In step S5, referring to FIGS. 14 and 15, with the second mask layer 16 serving as a mask, a portion of the second interlayer dielectric layer 18 is removed until the first mask layer 12 is exposed, and a first trench 191 is formed.

At the bottom of the first trench 191, the first mask layer 12 and the spacers 13 on both sides thereof are exposed. Of course, it is also possible that a portion of the second interlayer dielectric layer 18 is also exposed at the bottom of the first trench 191.

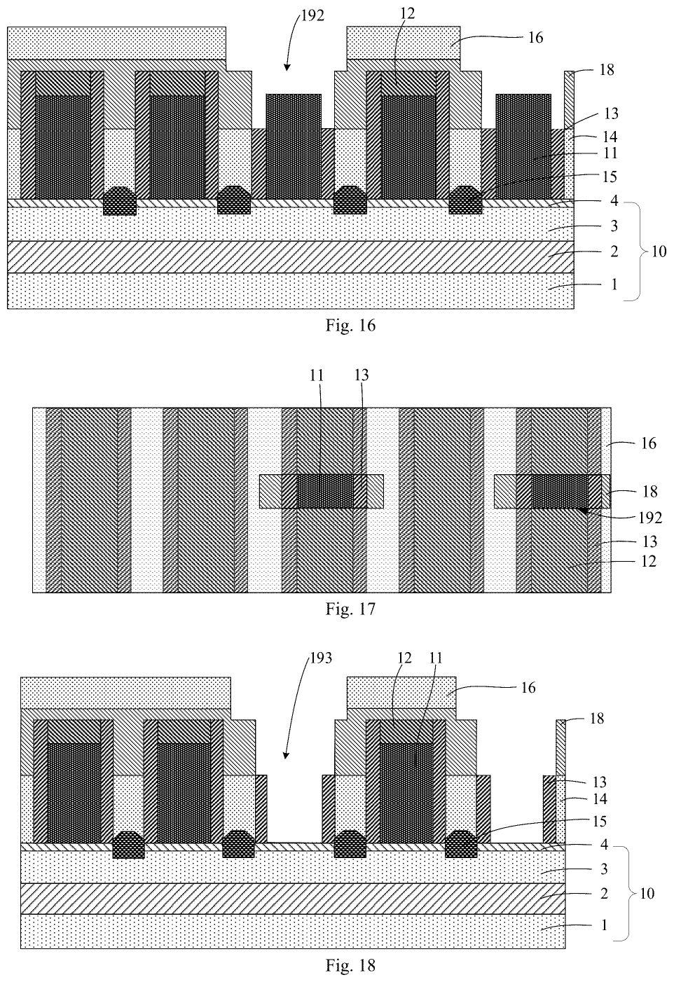

In step S6, referring to FIGS. 16 and 17, a second trench 192 is formed by removing the first mask layer 12 exposed in the first trench 191 and reducing the height of the spacers 13 on both sides thereof.

In this embodiment, with the second interlayer dielectric layer 18 serving as a mask, the first mask layer 12 and portions of the spacers 13 are removed. The remaining portions of the spacers 13 can prevent collapsing of the first interlayer dielectric layer 14 after the exposed gate structures 11 are subsequently removed, as well as damage to the sources/drains 15 during the removal of the gate structures 11.

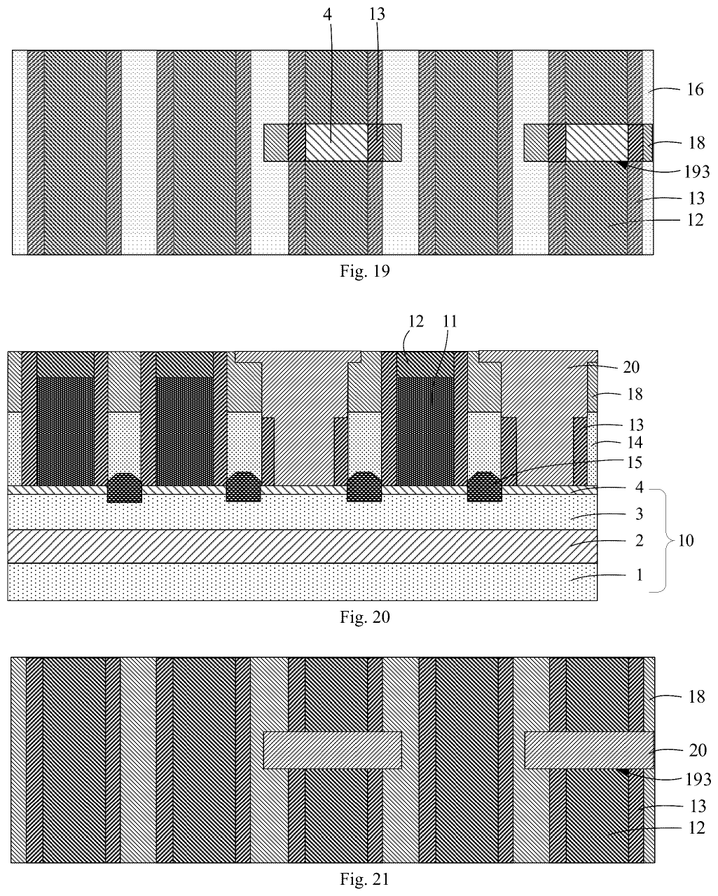

In step S7, referring to FIGS. 18 and 19, the gate structures 11 exposed in the second trench 192 are removed, resulting in the formation of a third trench 193.

In this embodiment, with the second interlayer dielectric layer 18 serving as a mask, the gate structures 11 are removed, exposing the substrate 10. The remaining portions of the spacers 13 on both sides of the removed gate structures 11 can prevent collapsing of the first interlayer dielectric layer 14 on the sides, as well as damage to the sources/drains 15 during the removal of the gate structures 11.

In step S8, referring to FIGS. 20 and 21, the second mask layer 16 is removed and a third interlayer dielectric layer 20 is filled in the third trench 193 and planarized until the first mask layer 12 is exposed.

In this embodiment, an initial third interlayer dielectric layer (not shown) is first formed, which fills up the third trench 193 and covers the second interlayer dielectric layer 18. The initial third interlayer dielectric layer and the second interlayer dielectric layer 18 are then planarized until the first mask layer 12 is exposed, resulting in the formation of the third interlayer dielectric layer 20.

The third interlayer dielectric layer 20 may be formed of the same material as the material of the second interlayer dielectric layer 18, such as silicon oxide, using an HDP-CVD process.

In the method of the present invention, portions of the first interlayer dielectric layer 14 are first removed so that its top is lower than a top of the first mask layer 12. The second interlayer dielectric layer 18 is then formed, which fills up the gaps between adjacent portions of the first mask layer 12 and covers the first mask layer 12. Subsequently, the second mask layer 16 is formed on the second interlayer dielectric layer 18 and etched so that the opening 17 is formed. As the second mask layer 16 is located on the second interlayer dielectric layer 18, the first mask layer 12 underlying the second interlayer dielectric layer 18 will not be damaged during the etching of the second mask layer 16. Thus, subsequent gate height loss can be prevented.

In addition, the remaining portions of the spacers 13 that survive from removing the exposed first mask layer 12 and reducing the height of the spacers 13 on both sides thereof can prevent collapsing of the first interlayer dielectric layer 14, as well as damage to the sources/drains 15 during the removal of the exposed gate structures 11.

Correspondingly, the present invention also provides a semiconductor device that can be fabricated according to the method as defined above.

Referring to FIGS. 20 and 21, the semiconductor device includes:
a substrate 10;
a plurality of gate structures 11 located on the substrate 10, the gate structures 11 formed on top thereof with a first mask layer 12, the gate structures 11 and the first mask layer 12 formed on side walls thereof with spacers 13;
a first interlayer dielectric layer 14 located on the substrate 10 between adjacent gate structures 11;
a second interlayer dielectric layer 18 located on the substrate 10 between adjacent gate structures 11 and located on the first interlayer dielectric layer 14;
a third trench 193 extending through a portion of the gate structure 11 and exposing a portion of the substrate 10 so as to provide a discontinuation for the gate structure 11, wherein lower portions of side walls of the third trench 193 are covered by the spacers 13; and
a third interlayer dielectric layer 20 filled in the third trench 193.

Referring to FIGS. 13 and 21, a total cross-sectional width of each gate structure 11 and the spacers 13 on its both sides are denoted as W1, a cross-sectional width between adjacent spacers 13 of adjacent gate structures 11 is denoted as W2 and a cross-sectional width of a top portion of the third trench 193 is denoted as W3, where W1≤W3≤W1+2*W2.

Referring to FIGS. 13 and 20, in this embodiment, the third trench 193 has three different cross-sectional widths: the cross-sectional width of the top portion that is equal to W3; a cross-sectional width of the middle portion that is equal to W1; and a cross-sectional width of the bottom portion that is equal to W1−2*Spacer Width. The bottom portion of the third trench 193 is a portion where its side walls are formed with the spacers 13. The top portion of the third trench 193 is a portion resulting from the partial removal of the second interlayer dielectric layer 18 in step S5. The middle portion of the third trench 193 is a portion located between the top and the bottom portions. The cross-sectional width of the top portion of the third trench 193 is greater than or equal to the cross-sectional width of the middle portion. The cross-sectional width of the middle portion is greater than the cross-sectional width of the bottom portion.

The description presented above is merely that of some preferred embodiments of the present invention and is not intended to limit the scope thereof in any sense. Any and all changes and modifications made by those of ordinary skill in the art based on the above teachings fall within the scope of the invention.

1. A method for fabricating a semiconductor device, comprising:
providing a substrate, on which a plurality of gate structures are formed, wherein a first mask layer is formed on tops of the gate structures, wherein spacers are formed on side walls of the gate structures and the first mask layer, wherein a first interlayer dielectric layer is formed on the substrate between adjacent gate structures, and wherein a top of the first interlayer dielectric layer is flush with a top of the first mask layer;
removing a portion of the first interlayer dielectric layer so that a top of the first interlayer dielectric layer is lower than the top of the first mask layer;
forming a second interlayer dielectric layer, wherein the second interlayer dielectric layer fills up gaps between adjacent portions of the first mask layer and covers the first mask layer;
forming a second mask layer on the second interlayer dielectric layer and forming at least one opening that exposes the second interlayer dielectric layer by etching the second mask layer, wherein the opening is aligned with at least a portion of the gate structure and the spacers on both sides thereof;
with the second mask layer serving as a mask, forming a first trench by removing a portion of the second interlayer dielectric layer until the first mask layer is exposed;
forming a second trench by removing the first mask layer exposed in the first trench and reducing a height of spacers on both sides thereof;
forming a third trench by removing the gate structure exposed in the second trench; and
removing the second mask layer, forming a third interlayer dielectric layer which fills up the third trench, and planarizing the third interlayer dielectric layer until the first mask layer is exposed.

2. The method according to claim 1, wherein a total cross-sectional width of each gate structure and spacers on both sides thereof is denoted as W1, wherein a cross-sectional width between adjacent spacers of adjacent gate structures is denoted as W2, and wherein a cross-sectional width of the opening is denoted as W3, where W1≤W3≤W1+2*W2.

3. The method according to claim 1, wherein removing a portion of the first interlayer dielectric layer by using a SiCoNi etching process.

4. The method according to claim 1, wherein the second interlayer dielectric layer and the third interlayer dielectric layer are formed using high-density plasma chemical vapor deposition (HDP-CVD) processes.

5. The method according to claim 4, wherein forming the second interlayer dielectric layer which fills up the gaps between the adjacent portions of the first mask layer and covers the first mask layer comprises:
forming an initial second interlayer dielectric layer, wherein the initial second interlayer dielectric layer covers the first interlayer dielectric layer and the first mask layer; and
planarizing the initial second interlayer dielectric layer to form the second interlayer dielectric layer, wherein a height difference between a top of the second interlayer dielectric layer and the top of the first mask layer lies within a predetermined range.

6. The method according to claim 5, wherein the predetermined range is from 200 Å to 600 Å.

7. The method according to claim 4, wherein forming the third interlayer dielectric layer which fills up the third trench and planarizing the third interlayer dielectric layer until the first mask layer is exposed comprises:
forming an initial third interlayer dielectric layer, wherein the initial third interlayer dielectric layer fills up the third trench and covers the second interlayer dielectric layer; and
performing a planarization process until the first mask layer is exposed.

8. The method according to claim 1, wherein the first mask layer is made of a same material as that of the spacer.

9. A semiconductor device fabricated according to the method according to claim 1, comprising:
a substrate;
a plurality of gate structures located on the substrate, wherein a first mask layer is formed on tops of the gate structures, and wherein spacers are formed on side walls of the gate structures and the first mask layer;
a first interlayer dielectric layer located on the substrate between adjacent gate structures;
a second interlayer dielectric layer located on the substrate between adjacent gate structures and located on the first interlayer dielectric layer;
a third trench extending through a portion of the gate structure and exposing a portion of the substrate so as to provide a discontinuation for the gate structure, wherein lower portions of side walls of the third trench are covered by the spacers; and
a third interlayer dielectric layer filled in the third trench.

10. The method according to claim 9, wherein a total cross-sectional width of each gate structure and spacers on both sides thereof is denoted as W1, wherein a cross-sectional width between adjacent spacers of adjacent gate structures is denoted as W2, and wherein a cross-sectional width of a top portion of the third trench is denoted as W3, where W1≤W3≤W1+2*W2.
